(19) United States
(12) Patent Application Publication
(10) Pub. No.: US 2023/0369014 A1
(43) Pub. Date: Nov. 16, 2023

(54) DOSE MAPPING AND SUBSTRATE ROTATION FOR SUBSTRATE CURVATURE CONTROL WITH IMPROVED RESOLUTION

(71) Applicant: Applied Materials, Inc., Santa Clara, CA (US)

(72) Inventor: Pradeep Subrahmanyan, Cupertino, CA (US)

(73) Assignee: Applied Materials, Inc., Santa Clara, CA (US)

(21) Appl. No.: 18/144,836

(22) Filed: May 8, 2023

Related U.S. Application Data
(60) Provisional application No. 63/341,817, filed on May 13, 2022.
(60) Provisional application No. 63/425,051, filed on Nov. 14, 2022.

(51) Int. Cl. H01J 37/304; H01J 37/317

(52) U.S. Cl. CPC H01J 37/304; H01J 37/3172; H01J 2237/20214; H01J 2237/30483

(57) ABSTRACT

A method may include generating a residual curvature map for a substrate, the residual curvature map being based upon a measurement of the substrate. The method may include generating a dose map based upon the residual curvature map, the dose map being for processing the substrate using a patterning energy source. The method may include applying the dose map to process the substrate using the patterning energy source, wherein the dose map is applied by performing a plurality of exposures of the substrate to the patterning energy source, at a plurality of different twist angles.

### CROSS-REFERENCE TO RELATED APPLICATION

This application claims priority to U.S. provisional patent application Ser. No. 63/341,817, filed May 13, 2022, entitled “DOSE MAPPING AND SUBSTRATE ROTATION FOR SUBSTRATE CURVATURE CONTROL WITH IMPROVED RESOLUTION,” and to U.S. provisional patent application Ser. No. 63/425,051, filed Nov. 14, 2022, entitled “DOSE MAPPING AND SUBSTRATE ROTATION FOR SUBSTRATE CURVATURE CONTROL WITH IMPROVED RESOLUTION,” and incorporated by reference herein in their entirety.

### FIELD

The present embodiments relate to stress control in substrates, and more particularly to stress compensation to reduce out of plane distortion in substrates.

### BACKGROUND

Devices such as integrated circuits, memory devices, and logic devices may be fabricated on a substrate such as a semiconductor wafer by a combination of deposition processes, etching, ion implantation, annealing, and other processes. Often, complete fabrication of devices and related circuitry may entail many hundreds of operations, including dozens of lithography operations. In particular, lithographic operations may require that a given mask to fabricate structures in a given region or level is to be aligned to preexisting structures.

One general concern for fabricating such devices and structures on a substrate such as a semiconductor wafer is the development of in-plane distortion (IPD) which distortion affects the overlay of a layer with respect to an underlying reference layer. IPD is a complex quantity affected by both the out-of-plane distortion (OPD) of the wafer and the alignment scheme employed in Photolithography. OPD is the fundamental wafer quantity and the signature of the residual OPD is critical to the achievable overlay. For example, a type of OPD often encountered is a global wafer curvature that may develop at many instances of processing due to stress buildup in the wafer as a result of processing operations.

Moreover, device processing may generate complex patterns of OPD across a wafer after at any given stage of processing that may tend to affect subsequent processing operations. As an example, a semiconductor wafer substrate may be patterned into regular arrays of die regions corresponding to die to be cut from the semiconductor wafer. The arrays of die regions may be associated with patterns of OPD that manifest themselves in a residual curvature having a high degree of directionality that is related to the die region layout. In a particular example, the complex patterns of OPD may generate overlay errors in a subsequent lithographic masking operation.

Recently, ion implantation of a backside of a wafer has been explored for modifying wafer stress, and thus modifying OPD. However, such approaches may employ ion beams that have a non-uniform shape that is not ideally suited to treat complex stress OPD patterns.

With respect to these and other considerations the present embodiments are provided.

### BRIEF DESCRIPTION OF THE DRAWINGS

FIGS. 1A-1G depict various stages in the generation of a residual curvature map for a substrate, according to embodiments of the disclosure;

FIG. 2 shows an exemplary beam profile that may be used to create a blur kernel to be applied to the residual curvature map of FIG. 1G;

FIG. 3A illustrates a blurred residual curvature map, according to some embodiments;

FIG. 3B shows an exemplary filtered residual curvature map generated by filtering the blurred residual curvature map of FIG. 3A;

FIG. 4 provides an exemplary ion dose map, according to embodiments of the disclosure;

FIG. 5A depicts a schematic top view of an ion implantation system for controlling substrate OPD in accordance with embodiments of the disclosure;

FIG. 5B, illustrates components of the ion implantation system of FIG. 5A, according to an embodiment;

FIG. 5C depicts a side view of an operation to implant a dose map, according to embodiments of the disclosure;

FIG. 5D presents an exemplary dose profile to illustrate ion dose as a function of radial position along a wafer;

FIGS. 6A-6C depict different configurations for reducing residual substrate curvature using a scanned ion beam, according to embodiments of the disclosure; and

FIG. 7 depicts an exemplary process flow.

### DETAILED DESCRIPTION

The present embodiments will now be described more fully hereinafter with reference to the accompanying drawings, where some embodiments are shown. The subject matter of the present disclosure may be embodied in many different forms and are not to be construed as limited to the embodiments set forth herein. Instead, these embodiments are provided so this disclosure will be thorough and complete, and will fully convey the scope of the subject matter to those skilled in the art. In the drawings, like numbers refer to like elements throughout.

The embodiments described herein relate to techniques and apparatus for improved control of stresses and the related out-of-plane distortion in a substrate, as well as control of the effects of OPD on subsequent substrate processing operations, such as device fabrication. The present embodiments may employ novel techniques to determine dose maps to be applied to a compensation layer of a substrate by a patterning energy source, in order to better correct OPD, and thus to reduce or minimize in-plane-distortion (IPD) that affects device fabrication and other patterning procedures. Non-limiting examples of patterning energy sources include an ion beam or a laser beam that are scannable with respect to a main plane of a substrate. In various embodiments, a patterning energy source may transfer a pattern a dose pattern into a substrate that involves a non-uniform, direct write, process. In this context, a ‘direct write’ process, including a direct write implant process, may refer to a process that employs relative movement of an ion beam or other beam without the use of a mask in order to produce a non-uniform dose pattern across a substrate surface. In some embodiments, a direct write process using a patterning energy source may involve an exposure to electrons, such as an electron beam, or photons, such as a laser beam, may be used to locally adjust curvature of a wafer.

In various embodiments detailed herein apparatus and techniques are provided to reduce substrate OPD using a patterning energy source in combination with substrate rotation. In particular embodiments, the residual curvature in a substrate is reduced using dose maps that are implemented to selectively process select regions of relatively higher curvature using a combination of a scanning an ion beam, substrate translation, and substrate rotation. In particular embodiments, a dose map may be implemented by determining a series of implant exposures to be performed at a series of different twist angles of a substrate, in order to improve resolution of implant procedure.

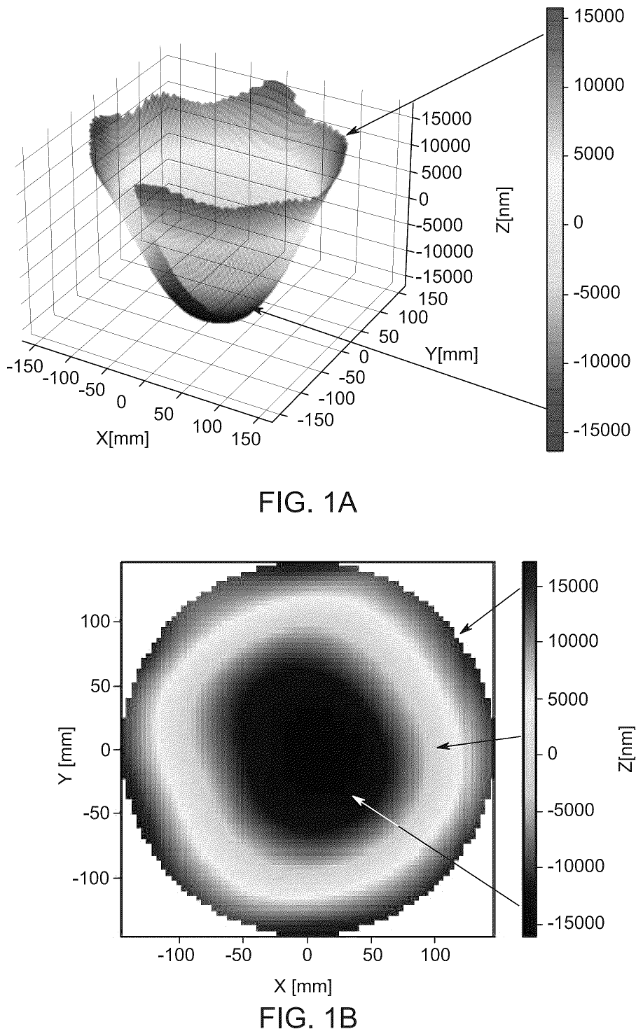

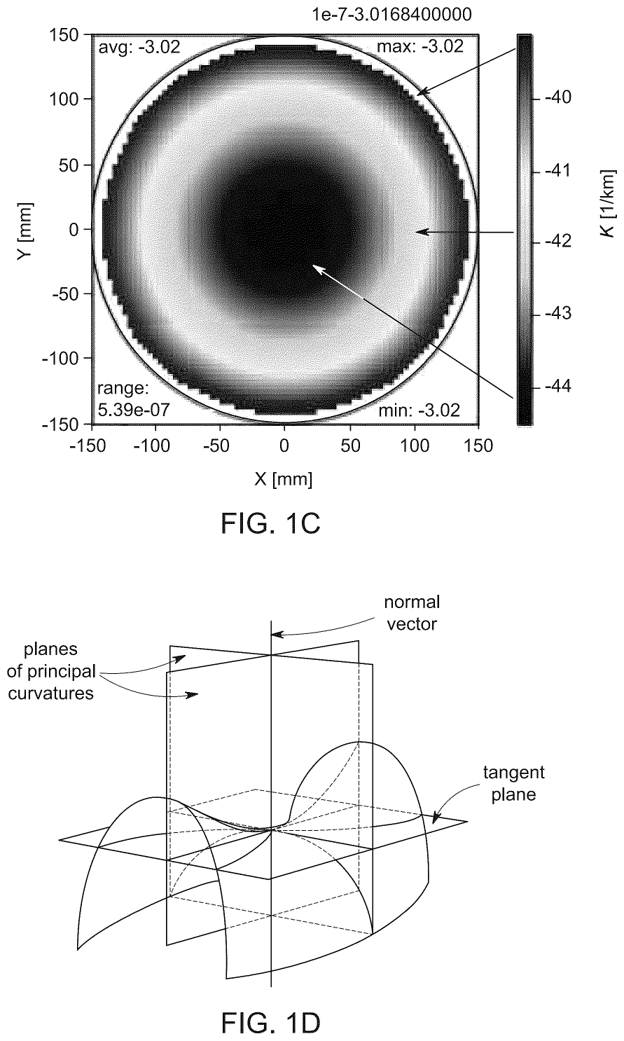

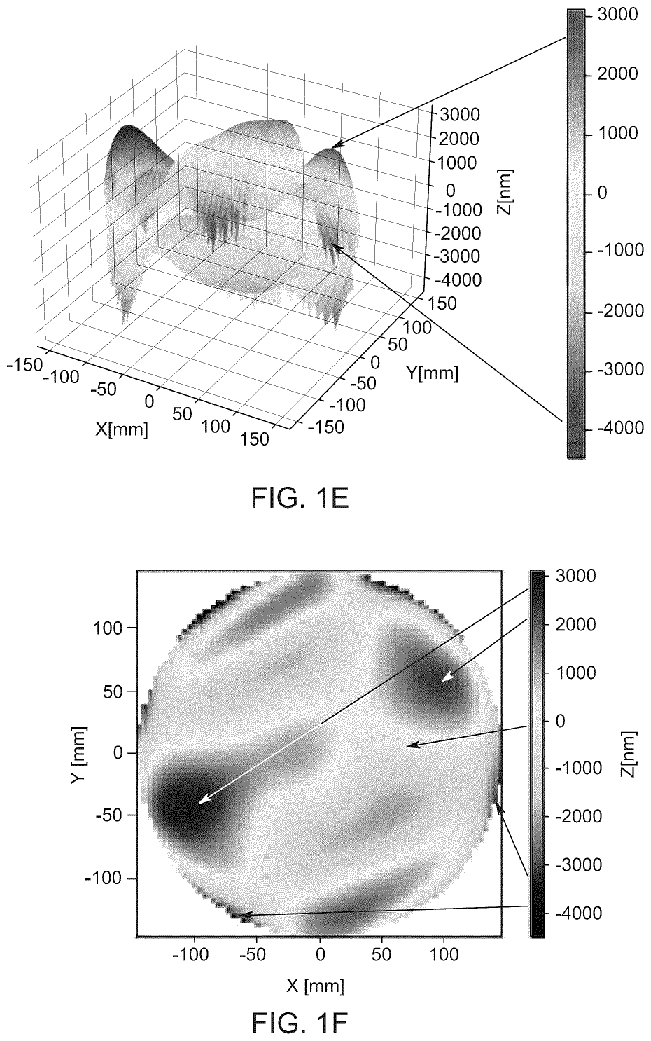

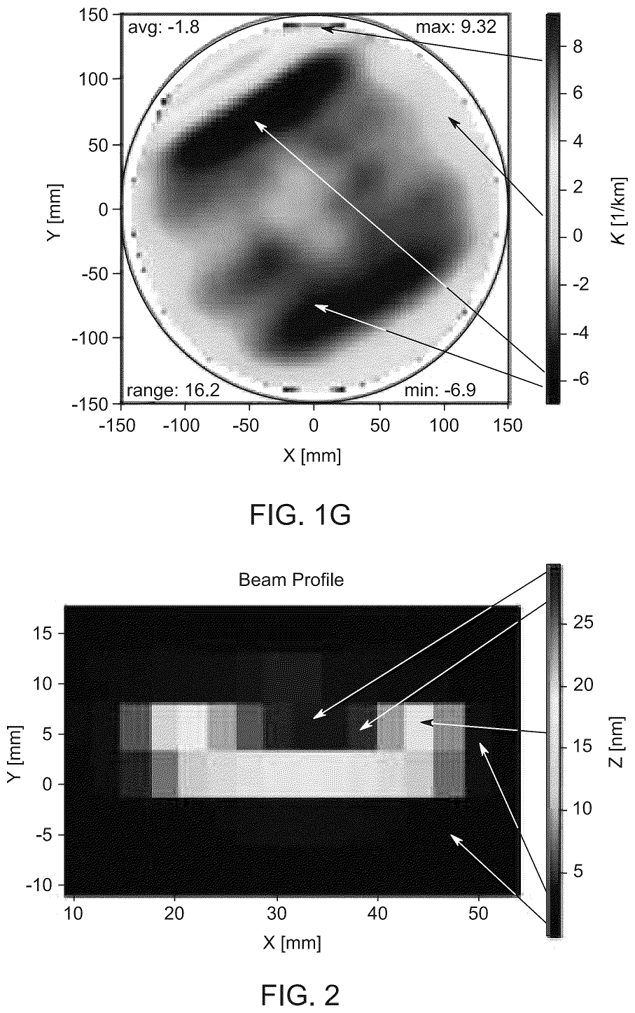

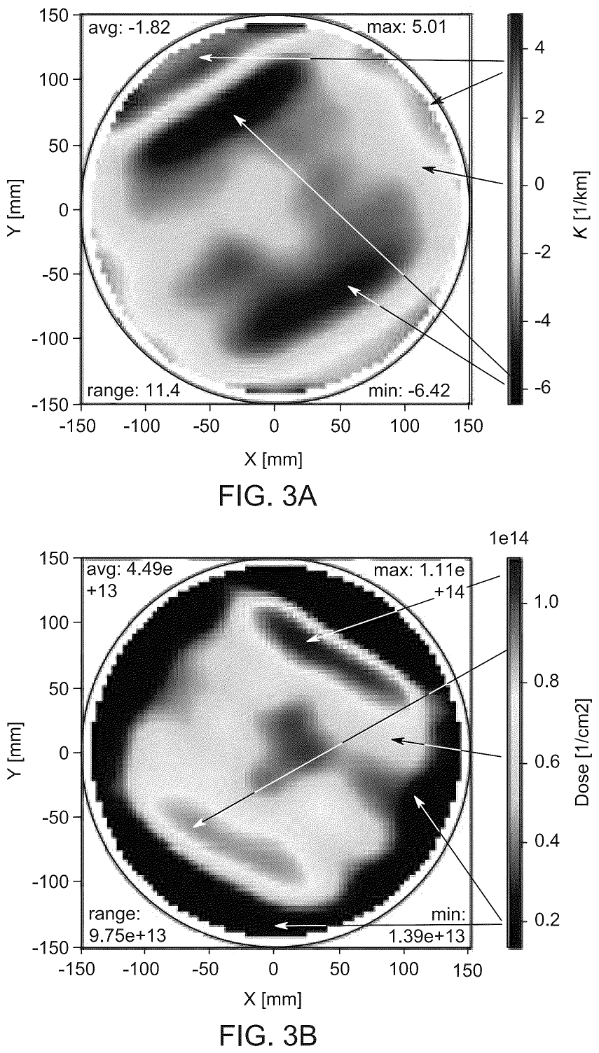

FIGS. 1A-1G depict a sequence of operations to be applied to determine a dose map for processing a substrate in order to compensate for substrate OPD in accordance with embodiments of the disclosure. In particular, the progression illustrated in FIGS. 3A-5C illustrates an approach to eliminate residual curvature in a substrate surface.

In FIGS. 1A-1C there are shown details for determining global curvature of a substrate in order to generate a global curvature map. FIG. 1A depicts a three dimensional representations of a wafer surface, shown as substrate surface map, or initial surface map, which surface may represent the measurement of a substrate using a known surface measurement tool, for example. FIG. 1B illustrates a two-dimensional representation of the surface of FIG. 1A, where the surface is generally paraboloid in nature. The range of OPD in this example is merely exemplary and may vary according to processing conditions, as will be appreciated by those of skill in the art. While the global curvature is intended to be removed, such as by using a blanket processing operation to form a blanket film on the back side, it may not always be possible to do so, due to process variations, such that a residual component of the global curvature still remains on the wafer. This global curvature still has a parabolic OPD signature and appears as a concentrated curvature near the middle of the wafer on a curvature map.

FIG. 1C depicts a global curvature map representing the values of curvature as a function of x,y coordinate over the wafer surface, based upon the initial surface map of FIG. 1A and FIG. 1B. The units κ are in inverse km. According to different non-limiting embodiments of the disclosure, the global curvature may be based upon a Gaussian curvature model or a mean curvature model. The modeling may be based upon the use of two mutually orthogonal principle planes of curvature, that extend perpendicularly to a tangent plane of the surface, as shown in FIG. 1D. In a Gaussian model, a product of the maximal and minimal curvatures is taken, where κ is given by

[symbol]

= [symbol] ₁ [symbol] ₂ (1)

In a mean model, a mean of the principal (maximal and minimal) curvatures is taken, where κ is given by

$$κ = \frac{1}{2} ( {κ}_{1} + {κ}_{2} ) \qquad Eq . ( 2 )$$

As shown in FIG. 1C the global curvature is nearly uniform over the entire wafer.

FIG. 1E depicts a three dimensional representations of the residual wafer surface corresponding to the same wafer whose global surface is shown in FIG. 1A, after extraction of the global curvature. In this example, the curvature model used to extract the global curvature component was a mean curvature model. FIG. 1F illustrates a two dimensional representation of the surface of FIG. 1E, after extraction of the parabolic term of the OPD.

FIG. 1G depicts a residual curvature map representing the values of curvature as a function of x,y coordinate over the wafer surface for the surface of FIGS. 1E and 1F. According to embodiments of the disclosure, the procedures as generally outlined above to model global curvature may be employed to generate the residual curvature map of FIG. 1G, based upon the OPD map of FIG. 1F. As shown in FIG. 1G the pattern of residual curvature shows a complex set of features. Generally, the curvature values over most of the wafer are relatively low, while a donut shaped region of negative curvature exists towards the center of the wafer. In some areas on the wafer, the curvature has a positive value, such as around the wafer periphery, and along the donut shaped region the curvature has a negative curvature value.

In accordance with embodiments of the disclosure, the residual curvature map of FIG. 1G may form the basis for a patterning ion implantation treatment to reduce or eliminate the OPD generating the features of the residual curvature map. In particular, a selective ion implantation pattern may be performed into a backside of the wafer represented by the curvature map of FIG. 1G. The selective ion implantation pattern may be designed to mimic the features of the residual curvature map so as to proportionately reduce the stress according to the degree of curvature at any location on a wafer surface. As detailed further below, in various embodiments of the disclosure, the selective ion implantation pattern may be implemented in a series of exposures at different wafer twist angles so as to improve the resolution of the implantation pattern when implemented in the substrate, and thus improve the resolution of the OPD reduction, particularly in regions of high substrate curvature.

In various embodiments of the disclosure, a residual curvature map may be transformed in a series of operations to generate a dose map that defines ion dose to be implanted into a substrate as a function of x,y position across a wafer surface. In turn, the dose map be implemented in a series of ion beam exposures at different wafer twist angles, where the ion beam is generally scanned along an x-axis in a given exposure, with optional translation of the substrate along the y-axis.

FIG. 2 shows an exemplary ion beam profile that may be used for actual ion implantation. This profile is used by a blur kernel operation to create a blur kernel to be applied to the residual curvature map of FIG. 1G, which map may be considered to be a raw residual curvature map. This operation may be used to create a blur kernel to be applied to the residual curvature map of FIG. 1G to attenuate the effect of high spatial frequencies on the implanter. This blur kernel may then be used to generate a blurred residual curvature map, shown in FIG. 3A.

The blurred residual curvature map of FIG. 3A presents the same qualitative pattern of positive curvature and negative curvature regions, while the width of the regions is broader and the curvature values within the regions differ somewhat from their unblurred counterparts. This blurred curvature map may be more suitable for implementation by a patterning energy source, such as a scanning ion beam, taking into account the finite size of the ion beam.

Turning to FIG. 3B, there is shown a filtered residual curvature map that is generated by filtering the blurred residual curvature map of FIG. 3A in order to remove all positive terms of curvature, which positive curvature cannot be influenced by the ion beam. As a result, two major, somewhat linear regions of relatively higher negative curvature remain, as well as some regions of lesser negative curvature protruding from the linear regions. This map may then be converted into a dose map, such as for a scannable ion beam, where the total ion dose to be applied over the two dimensional surface of the wafer (x-y plane) is based upon the curvature map features of FIG. 3B. Thus, the pattern of ion dose for a suitable dose map may exhibit features having the same shapes as the features of the curvature map.

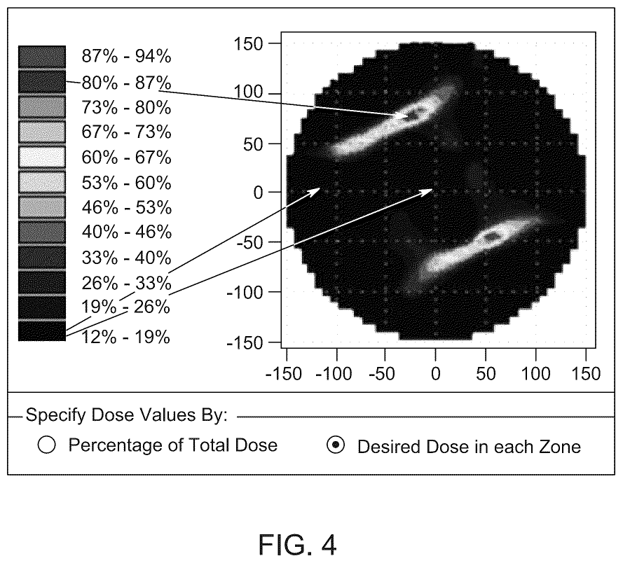

FIG. 4 provides an exemplary ion dose map, based upon the filtered curvature map of FIG. 3B, where the dose map exhibits qualitatively similar pattern as the curvature map of FIG. 3B. In this example, the two parallel linear regions of the dose map, corresponding to the high curvature linear regions of the filtered curvature map are to receive substantially higher dose than the general ‘background’ regions. For example, the background regions, over most of the surface of the wafer, are to receive a relative ion dose in the range of 15%, while the linear regions are to receive a relative ion dose ranging between approximately 50% and 85%.

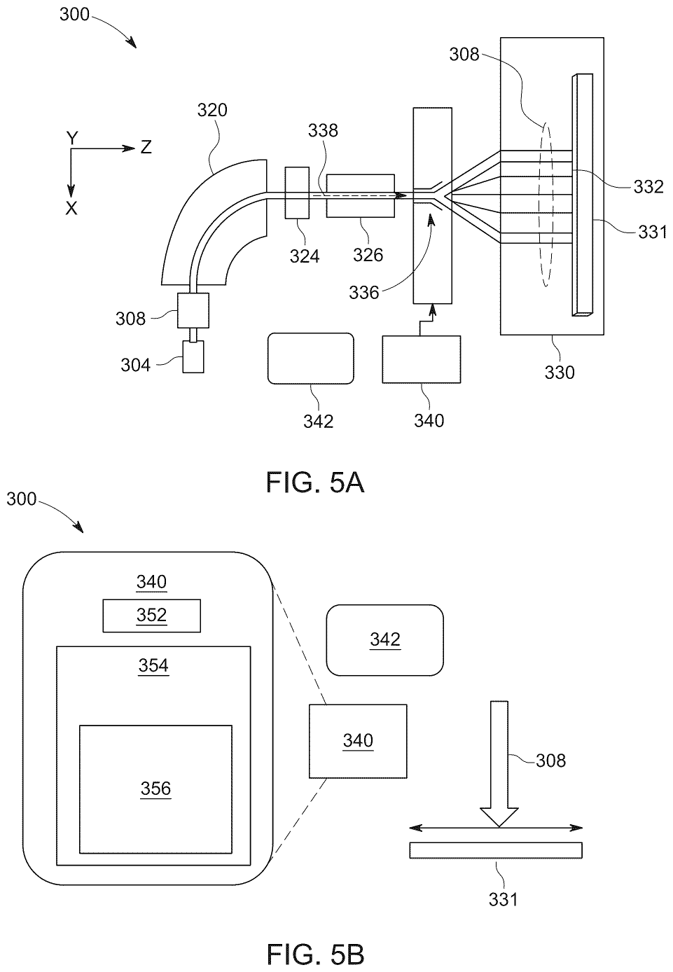

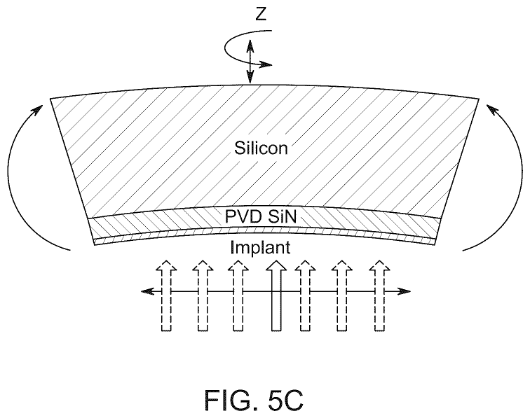

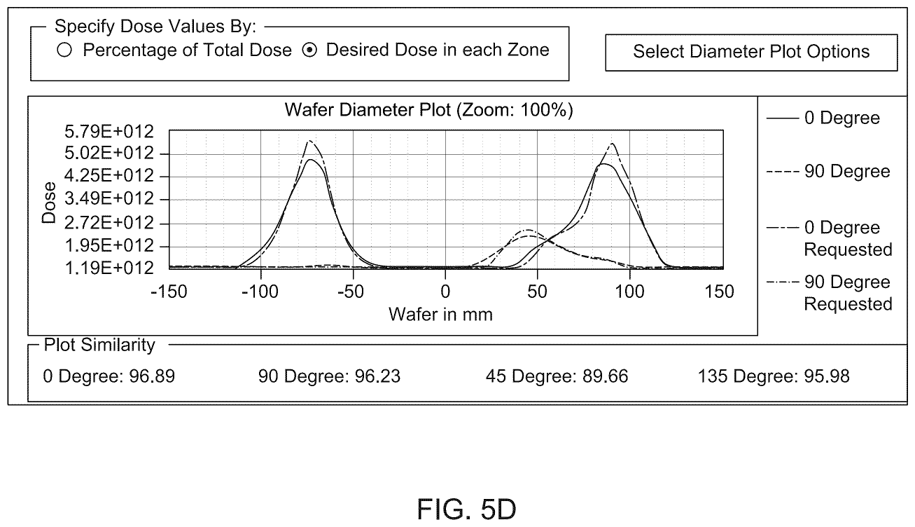

FIG. 5A depicts a schematic top view of an ion implantation system for controlling substrate OPD in accordance with embodiments of the disclosure. The ion implantation system, referred to as ion implanter 300, represents a process chamber containing, among other components, an ion source 304 for producing an ion beam 308, and a series of beam-line components. The ion source 304 may comprise a chamber for receiving a flow of gas and generating ions. The ion source 304 may also comprise a power source and an extraction electrode assembly (not shown) disposed near the chamber. The beam-line components may include, for example, an analyzer magnet 320, a mass resolving slit (MRS) 324, a steering/focusing component 326, and end station 330, including substrate holder 331.

The ion implanter 300 further includes a beam scanner 336 positioned along a beamline 338 between the MRS 324 and the end station 330. The beam scanner 336 may be arranged to receive the ion beam 308 as a spot beam and to scan the ion beam 308 along a fast scan direction, such as parallel to the X-Axis in the Cartesian coordinate system shown. Notably, the substrate 332 may be scanned along the Y-axis, so a given ion treatment may be applied to a given region of the substrate 332 as the ion beam 308 is simultaneously scanned back and forth along the X-axis. The ion implanter 300 may have further components, such as a collimator as known in the art (not shown for clarity), to direct ions of the ion beam 308, after scanning, along a series of mutually parallel trajectories to the substrate 332, as suggested in FIG. 5A. In various embodiments, the ion beam may be scanned at a frequency of several Hz, 10 Hz, 100 Hz, up to several thousand Hz, or greater. For example, the beam scanner 336 may scan the ion beam 308 using magnetic or electrostatic scan elements, as known in the art.

By scanning the ion beam 308 rapidly over a fast scan direction, such as back and forth over along the X-axis, the ion beam 308, configured as a spot beam, may deliver a targeted ion dose for any given region of the substrate in the x-y plane. Suitable ions for ion beam 308 may include any ion species capable of inducing a stress change at a suitable ion energy, including ions such as phosphorous, boron, argon, indium BF₂, according to some non-limiting embodiments, with ion energy being tailored according to the exact ion species used. To implement a dose map, the scan speed of the ion beam along the x-axis may be modulated at different locations of the substrate 332 so as to deliver a different ion dose at the different locations, in accordance with the dose map. Generally, the ion beam 308 may be scanned back and forth across a substrate for any suitable number of scans, with an accompanying scanning of the substrate in an orthogonal direction to the beam scan direction, until the targeted dose as specified by a dose map is received at reach region across the substrate 332.

For example, the ion implanter 300 may further include a controller 340, coupled to the beam scanner 336, to coordinate operation of the beam scanner 336, as well as a substrate platen or substrate stage 331. As further shown in FIG. 5A, the ion implanter 300 may include a user interface 342, also coupled to the controller 340. The user interface 342 may be embodied as a display, and may include user selection devices, including touch screens, displayed menus, buttons, knobs, and other devices as known in the art. According to various embodiments, the user interface 342 may send instructions to the controller 340 to generate an appropriate implant pattern, which pattern may implement an appropriate dose map for the substrate 332.

As further shown in FIG. 5B, the controller 340 may include a processor 352, such as a known type of microprocessor, dedicated processor chip, general purpose processor chip, or similar device. The controller 340 may further include a memory or memory unit 354, coupled to the processor 352, where the memory unit 354 contains a dose map routine 356. The dose map routine 356 may be operative on the processor 352 to manage scanning of the ion beam 308 and substrate 332 in order to impart a calculated dose map into the substrate 332. The memory unit 354 may comprise an article of manufacture. In one embodiment, the memory unit 354 may comprise any non-transitory computer readable medium or machine readable medium, such as an optical, magnetic or semiconductor storage. The storage medium may store various types of computer executable instructions to implement one or more of logic flows described herein. Examples of a computer readable or machine-readable storage medium may include any tangible media capable of storing electronic data, including volatile memory or non-volatile memory, removable or non-removable memory, erasable or non-erasable memory, writeable or re-writeable memory, and so forth. Examples of computer executable instructions may include any suitable type of code, such as source code, compiled code, interpreted code, executable code, static code, dynamic code, object-oriented code, visual code, and the like. The embodiments are not limited in this context.

In one implementation, a dose map may be used to perform an implantation into a stress control layer on a backside of a substrate. FIG. 5C depicts a side view of an operation to implant a dose map, where the ion beam is scanned along a fixed direction, in order to implant an implant species into the a stress compensation layer, such as silicon nitride. By selectively controlling parameters such as beam scan rate, the ion dose imparted to different locations of the stress compensation layer can be varied, thus varying the change in stress as a function of position across the wafer, as well as the related substrate curvature.

FIG. 5D presents an exemplary dose profile to illustrate ion dose as a function of radial position along a wafer, where the dose profile may be implemented by scanning an ion beam from left to right across a wafer, while selectively altering a parameter such as scan rate, in order to selectively increase ion dose at the peak regions of the profile. For implementing a two-dimensional dose map, such as the dose map of FIG. 4, the wafer may be scanned in a wafer scan direction, orthogonal to the beam scan direction, while the ion beam is selectively scanned along the beam scan direction. In addition, As detailed below, according to embodiments of the disclosure the substrate may be rotated about the z-axis between a series of exposures to a scanned ion beam in order to transfer the pattern of a dose map into an implant pattern in the substrate with improved resolution.

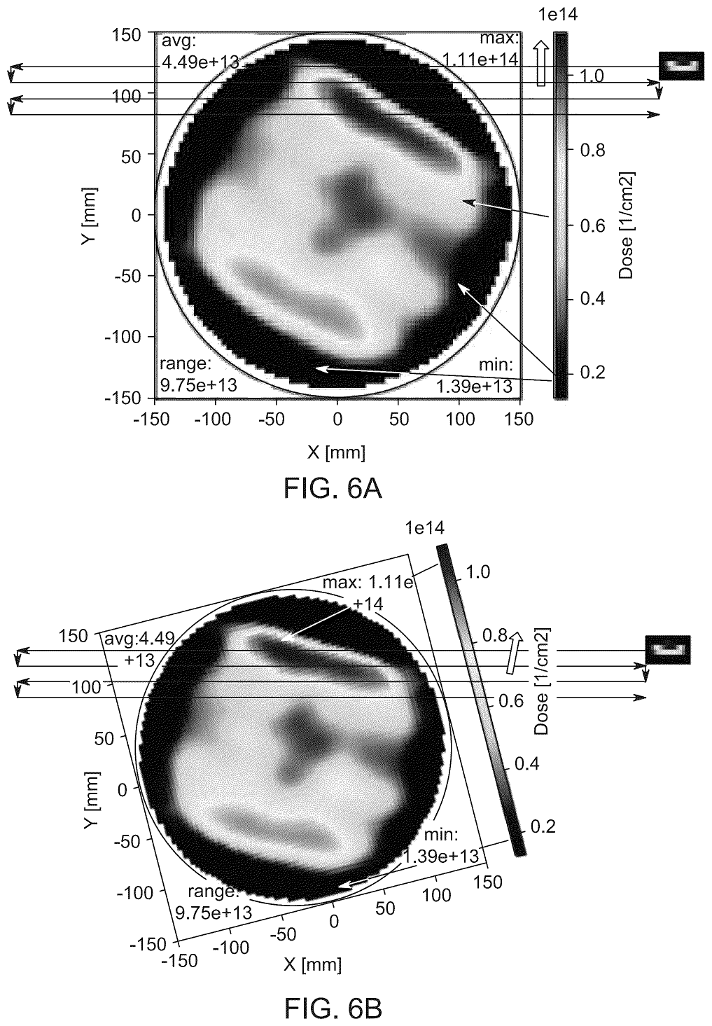

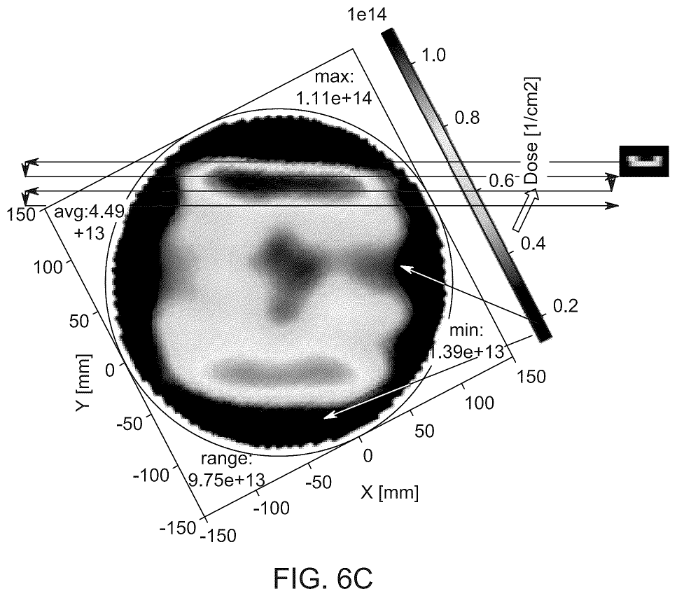

FIGS. 6A-6C depict different configurations for reducing residual substrate curvature using a scanned ion beam, according to embodiments of the disclosure. These figures present a composite image showing a two dimensional representation of a filtered residual curvature map, discussed previously, together with a pattern of scanning an ion beam, shown in the circuitous path. Generally, the ion beam is rapidly scanned along a fixed-axis in a given exposure, with or without scanning of the substrate at the same time. In the example of FIG. 6A, the ion beam is scanned along the x-axis of the Cartesian coordinate system shown. The substrate may be moved along the direction of the bold arrow, in this case, parallel to the y-axis, either intermittently, or continuously during the scanning of the ion beam, so that an entirety of the substrate may be exposed to the ion beam. Note that the scan rate of the ion beam along the x-axis may be in the range of several hundred to thousands of Hz for a ˜450 mm scan distance, in some examples, translating into a scan period in the range of a few hundred microseconds. At the same time, the scan rate of the substrate along the y-axis may be on the order of millimeters per second. Thus, during the time period elapsed over an individual scan the substrate may be considered quasi-stationary.

Note also that a dose map that is calculated to theoretically eliminate the residual curvature shown may exhibit the same geometrical pattern as the residual curvature map (compare FIGS. 3B and 4), where the ion dose to be implanted into a particular point on the substrate, represented by an x,y coordinate, is proportional to the magnitude of the residual curvature at that point. Thus, for the purposes of clarity of explanation, the residual curvature map of FIG. 6A may be considered a proxy for the dose map (FIG. 4) used to eliminate the residual curvature of FIG.

6A.

During ion beam scanning, the total ion dose implanted at a given x-y point will be determined by, among other factors, the ion beam current density at that point, and the ion beam scan speed at that point, for each scan among up to several thousand scans that may cover that point. Moreover, ion beam current density for a given point will be affected by the beam shape or beam profile, which profile in general may be non-uniform. Since the residual curvature pattern of FIG. 6A exhibits several areas of non-uniform degree of curvature, an ion beam exposure to best eliminate these areas may vary the scan speed as a function of position, while the substrate is scanned along the y-axis. As shown in FIG. 6A, the two major areas of high residual curvature extend along a direction exhibiting an approximately 30 degrees rotation or twist with respect to the x-axis. Thus, for the configuration of FIG. 6A, where the wafer is oriented so that the substrate is scanned parallel to the y-axis and the beam is scanned parallel to the x-axis, the scan direction of the ion beam does not align with the long direction of the high curvature features. In order to implement a dose map that matches the residual curvature map, that is, to impart the proper ion dose into these high curvature regions while scanning an ion beam at a 30 degree twist angle with respect to the long direction of the features, the precise control of the variation of the scan speed of the ion beam may be quite challenging. Moreover, because of a non-uniform beam profile, the resolution of the ion beam for transferring the desired dose map into the substrate may be less than optimal using the scanning configuration of FIG. 6A.

In accordance with various embodiments of the disclosure, the resolution for transferring a dose map into an implant pattern in a substrate may be improved by performing a routine that includes a series of exposures to a scanning ion beam, where the twist angle of the substrate is varied between sucessive exposures. In a given exposure, the ion beam is scanned along a fixed direction, which direction is characterized by a given twist angle with respect to a fixed axis of the substrate, such as the x-axis. In the example of FIG. 6A, the twist angle for the exposure is zero degrees, meaning the ion beam is scanning parallel to the x-axis. Turning to FIG. 6B, there is shown a configuration where the twist angle is approximately 15 degrees, while in FIG. 6C, the configuration exhibits a twist angle of approximately 30 degrees, matching the angle of inclination of the high curvature features with respect to the x-axis. Thus, a dose map may be transferred into an implant pattern in the substrate using a series of exposures at different twist angles, as exemplified by FIGS. 6A-6C, with improved resolution as compared to scanning an ion beam at a single twist angle. Note that in order to implement a dose map, computations for each scan profile for the ion beam for exposures at different twist angles may be performed in the frequency domain since convolutions are easily reduced to multiplications.

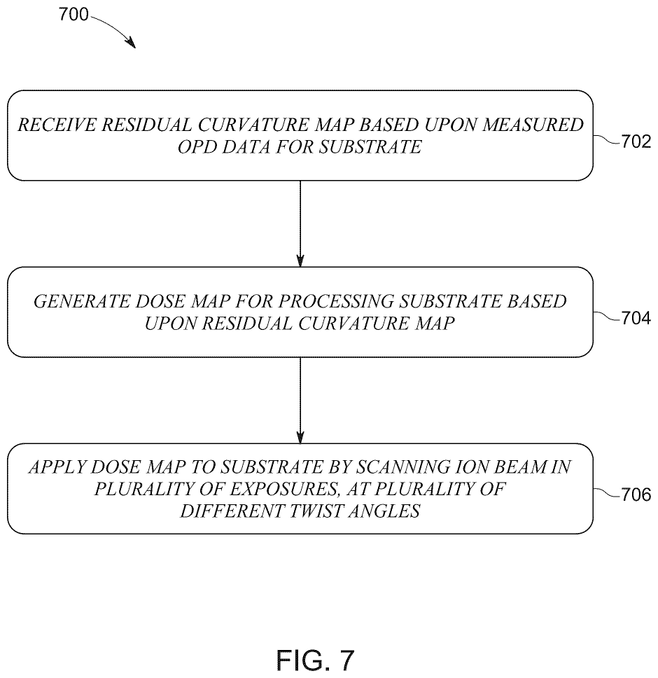

Turning now to FIG. 7, there is shown a process flow 700, according to some embodiments of the disclosure. At block 702, a residual curvature map is received, based upon measured OPD data for a substrate. The residual curvature map may plot substrate curvature in inverse length as a function of x,y location across the substrate in question. The residual curvature map may be determined from a residual surface for the substrate that is extracted after a global curvature map is removed.

As such, the a global curvature map may be generated using a model to model an initial substrate surface that plots the magnitude of OPD as a function of x,y position across a putative flat substrate surface. In some examples, the surface may be modeled as a paraboloid using a mean model or Gaussian model, as detailed hereinabove.

At block 704, a dose map for processing the substrate is generated based upon the residual curvature map. The dose map in some implementations may be determined by first applying using a blur kernel to the residual curvature map to generate a blurred residual curvature map, accounting for size effects of an ion beam to apply the dose map, for example. In some instances, the blurred residual curvature map may be filtered further to produce the dose map. For example, a positive curvature filter may be applied to remove positive curvature elements from the blurred residual curvature map, since positive curvature components may not be amenable to treatment by an implanting ion beam. The dose map may then be produced based upon a filtered residual curvature map, where the dose map may present a qualitatively similar pattern as the filtered residual curvature map where relative dose is increased in x,y regions of relative higher curvature.

At block 706, the dose map is applied to the substrate by scanning an ion beam along a fixed direction in a plurality of exposures, at a plurality of different twist angles. The scan speed profile for each of the exposures may be varied in a manner so that the total ion dose imparted into the substrate as a function of position matches the dose map.

Advantages provided by the present embodiments are multifold. As a first advantage, the present approach allows subsequent device to proceed with more accuracy, such as subsequent lithography steps requiring low in plane distortion. As a second advantage, the present approach more accurately reduces regions of greater in plane distortion by targeting residual areas of greater substrate curvature for greater energetic treatment. As a third advantage, the present embodiments provide a more accurate approach to reducing residual or local substrate curvature by rotating a substrate through multiple exposures to increase resolution of a scanning ion beam for transferring a desired pattern of implantation into the substrate.

The present disclosure is not to be limited in scope by the specific embodiments described herein. Indeed, other various embodiments and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose, yet those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method, comprising:
generating a residual curvature map for a substrate, the residual curvature map being based upon a measurement of the substrate;
generating a dose map based upon the residual curvature map, the dose map being for processing the substrate using a patterning energy source; and
applying the dose map to process the substrate using the patterning energy source, wherein the dose map is applied by performing a plurality of exposures of the substrate to the patterning energy source, at a plurality of different twist angles.

2. The method of claim 1, wherein the generating the residual curvature map comprises:
subtracting a global curvature map from an initial surface map of the substrate, to generate a raw residual curvature map; and
applying a blur kernel operation to the raw residual curvature map.

3. The method of claim 2, the generating the residual curvature map further comprising applying a filter to filter out positive curvature from the residual curvature map.

4. The method of claim 2, wherein a substrate curvature represented by the global curvature map is removable by a blanket processing operation.

5. The method of claim 1, the patterning energy source comprising an ion beam, electron beam or a laser beam.

6. The method of claim 5, wherein the patterning energy source is scanned along a first direction within a main plane of a substrate platen supporting the substrate, during the plurality of exposures, and
wherein the substrate is rotated through a twist angle about an axis extending perpendicularly to the main plane of the substrate platen between successive exposures of the plurality of exposures.

7. The method of claim 1, wherein the applying the dose map comprises:
exposing a stress compensation layer on a backside of the substrate to the patterning energy source, and
scanning the patterning energy source over the stress compensation layer in a pattern in order to transfer the dose map into the substrate, without using a mask.

8. A method, comprising:
receiving a substrate surface map of a substrate, comprising a map of out-of-plane distortion of the substrate;
modeling a global curvature map from the substrate surface map;
generating a residual curvature map after extracting the global curvature map from the substrate surface map;
generating a dose map based upon the residual curvature map, the dose map being for processing the substrate using a patterning energy source; and
applying the dose map to process the substrate using the patterning energy source, wherein the dose map is applied by performing a plurality of exposures of the substrate to the patterning energy source, at a plurality of different twist angles.

9. The method of claim 8, wherein the generating the residual curvature map comprises:
subtracting the global curvature map from an initial surface map of the substrate, to generate a raw residual curvature map; and
applying a blur kernel operation to the raw residual curvature map.

10. The method of claim 9, the generating the residual curvature map further comprising applying a filter to filter out positive curvature from the residual curvature map.

11. The method of claim 9, wherein a substrate curvature represented by the global curvature map is removable by a blanket processing operation.

12. The method of claim 8, the patterning energy source comprising an ion beam, electron beam or a laser beam.

13. The method of claim 12, wherein the patterning energy source is scanned along a first direction within a main plane of a substrate platen supporting the substrate, during the plurality of exposures, and
wherein the substrate is rotated through a twist angle about an axis extending perpendicularly to the main plane of the substrate platen between successive exposures of the plurality of exposures.

14. The method of claim 8, wherein the applying the dose map comprises:
exposing a stress compensation layer on a backside of the substrate to the patterning energy source, and
scanning the patterning energy source over the stress compensation layer in a pattern in order to transfer the dose map into the substrate, without using a mask.

15. A method, comprising:
receiving a substrate surface map of a substrate, comprising a map of out-of-plane distortion (OPD) of the substrate based upon a set of measured OPD;
generating a global curvature map from the substrate surface map using a model;
extracting a residual surface based upon the substrate surface map and the global curvature map;
generating a raw residual curvature map based upon the residual surface;
generating a dose map based upon the raw residual curvature map; and
applying the dose map to process the substrate using a patterning energy source, wherein the dose map is applied by performing a plurality of exposures of the substrate to the patterning energy source, at a plurality of different twist angles.

16. The method of claim 15, wherein the generating the dose map based upon the raw residual curvature map comprises:
applying a blur kernel operation to the raw residual curvature map to generate a blurred residual curvature map.

17. The method of claim 16, the generating the generating the dose map based upon the raw residual curvature map comprises further comprising applying a filter to filter out positive curvature from the blurred residual curvature map.

18. The method of claim 15, the patterning energy source comprising an ion beam, electron beam or a laser beam.

19. The method of claim 15, wherein the patterning energy source is scanned along a first direction within a main plane of a substrate platen supporting the substrate, during the plurality of exposures, and
wherein the substrate is rotated through a twist angle about an axis extending perpendicularly to the main plane of the substrate platen between successive exposures of the plurality of exposures.

20. The method of claim 15, wherein the applying the dose map comprises:
exposing a stress compensation layer on a backside of the substrate to the patterning energy source, and
scanning the patterning energy source over the stress compensation layer in a pattern in order to transfer the dose map into the substrate, without using a mask.
